(19) United States
(12) Patent Application Publication
(10) Pub. No.: US 2007/0146016 A1
(43) Pub. Date: Jun. 28, 2007

(54) Signal output circuit and power source voltage monitoring device using the same

(75) Inventor: Makoto Yasusaka, Kyoto (JP)

Correspondence Address: ROHM CO., LTD.;C/O KEATING & BENNETT, LLP, 8180 GREENSBORO DRIVE, SUITE 850, MCLEAN, VA, 22102, US

(73) Assignee: ROHM CO., LTD., Ukyo-ku, Kyoto (JP)

(21) Appl. No.: 10/596,727

(22) PCT Filed: Dec. 20, 2004
(86) PCT No.: PCT/JP04/18997

§ 371 Date: Jun. 22, 2006

(30) Foreign Application Priority Data
Dec. 26, 2003 (JP) 2003-435187

(51) Int. Cl. H03K 5/22

(52) U.S. Cl. 327/72

(57) ABSTRACT

A signal output circuit that can decrease the current consumption while securing the base current of an output transistor of an NPN type bipolar transistor includes an output transistor of the NPN type bipolar transistor, a ground side output control transistor of which turning ON turns OFF the output transistor, a base current supply resistive element for supplying current to the base of the output transistor, a power supply side output control transistor which is disposed between the base current supply resistive element and the base of the output transistor, a ground side current bypass transistor which turns ON and OFF in the same way as the ground side output control transistor according to the input signal so that turning ON allows the current of the base current supply resistive element to flow, and a current limitation resistive element which is disposed between the ground side current bypass transistor and the base current supply resistive element.

### BACKGROUND OF THE INVENTION

1. Field of the Invention

The present invention relates to a signal output circuit for outputting an output signal from an NPN type bipolar transistor, and a power supply voltage monitoring device for outputting a power supply voltage monitoring signal from the signal output circuit.

2. Description of the Related Art

For a system that includes electronic circuits, a power supply voltage monitoring device (reset device) for outputting a power supply voltage monitoring signal (reset signal) for stopping the system operation when the power supply voltage is lower than a predetermined value, is widely used to prevent malfunctions due to the power supply voltage which is the applied voltage (e.g., Japanese Patent Application Laid-open No. H11-220370).

FIG. 2 is a conventional power supply voltage monitoring device. This power supply voltage monitoring device 101 includes a signal output circuit 102 for outputting a power supply voltage monitoring signal, to indicate that the power supply voltage V_{cc} being monitored is lower than a predetermined value, to the output terminal OUT, resistive elements 23 and 24 connected in series for dividing the power supply voltage V_{cc}, a reference voltage generation circuit 22 for generating the reference voltage V_{REF}, a comparator 25 where voltage, at the mid-point of the resistive elements 23 and 24 connected in series, is input to the non-inversion input terminal, the reference voltage V_{REF}, generated by the reference voltage generation circuit 22, is input to the inversion input terminal, and these are compared and the comparison output thereof is generated as the input signal of the signal output circuit 102, a pull-down resistive element 26 which is connected to the output of the comparator 25 and has its other end grounded, and a constant voltage generation circuit 21 for supplying a predetermined constant voltage V_{c} to the power supply terminals of the reference voltage generation circuit 22 and the comparator 25. Another electronic circuit (not illustrated) for inputting the power supply voltage monitoring signal is connected to the outside of the output terminal OUT.

The signal output circuit 102 also includes an output transistor 110 of the NPN type bipolar transistor for outputting the power supply voltage monitoring signal to the output terminal OUT, a ground side output control transistor 111 of an N type MOS transistor which turns ON and OFF according to the input signal, so that turning ON drops the potential of the base of the output transistor 110 to turn OFF the output transistor 110, and turning OFF raises the potential of the base of the output transistor 110 to turn ON the output transistor 110, and a base current supply resistive element 112 for supplying current from the input power supply (power supply voltage V_{cc}) to the base of the output transistor 110. The reason why the output transistor 110 is the NPN type bipolar transistor is because the voltage at the ground side to be input to another electronic circuit (not illustrated) connected to the output terminal OUT drops with certainty to a voltage close to the ground potential.

The reference voltage V_{REF} (e.g., 0.7V) of the power supply voltage monitoring device 101 requires high precision, so the reference voltage generation circuit 22 is constructed using a band gap voltage source, for example. The constant voltage V_{c} (e.g., 4V) is for stably operating the reference voltage generation circuit 22 and the comparator 25, and the constant voltage generation circuit 21 has a relatively simple configuration primarily of diodes connected in series, for example. The output of this constant voltage generation circuit 21 has high impedance if the power supply voltage V_{cc} to be input is the constant voltage V_{c} or less, and in this case, the output of the comparator 25 also has high impedance and the input signal of the signal output circuit 102 is fixed to the ground potential level by the pull-down resistive element 26. In other words, until the reference voltage generation circuit 22 and the comparator 25 operate, the output transistor 110 becomes ON status with certainty, and the power supply voltage monitoring signal indicates that the power supply voltage V_{cc} is lower than a predetermined value. Also, if the power supply voltage V_{cc} to be input is higher than the constant voltage V_{c}, the power supply voltage monitoring device 101 operates as follows.

If the divided power supply voltage V_{cc} (voltage at the mid-point of the resistive elements 23 and 24 connected in series) is lower than the reference voltage V_{REF}, the comparator 25 outputs low level to the signal output circuit 102 as the comparison output, and thus, the ground side output control transistor 111 turns OFF. As a result, the output transistor 110 turns ON and the power supply voltage monitoring signal indicates that the power supply voltage V_{cc} is lower than a predetermined value.

The current I₁ that flows through the base current supply resistive element 112 becomes the base current of the output transistor 110, and the output current I₀, which is the base current multiplied by the current amplification factor (h_{FE}), flows to the output transistor 110. The output current I₀ flows as the power supply voltage monitoring signal via the output terminal OUT, and the input voltage of another electronic circuit (not illustrated) drops to the ground side by the output current I₀. The resistance value of the base current supply resistive element 112 is determined considering the value of the output current I₀. For example, if the value of the output current I₀ to be required is 2 mA, and h_{FE} is 200, then the base current of the output transistor 110 requires 10 μA. If the output transistor 110 turns ON when the power supply voltage V_{cc} is 10V, then the resistance value of the base current supply resistive element 112 is about 1 MΩ.

If the voltage of the divided power supply voltage V_{cc} is higher than the reference voltage V_{REF}, the comparator 25 outputs the high level to the signal output circuit 102 as the comparison output, and thus, the ground side output control transistor 111 turns ON. As a result, the potential of the base of the output transistor 110 drops and the output transistor 110 turns OFF, and the power supply voltage monitoring signal indicates that the power supply voltage V_{cc} is higher than a predetermined value.

At this time the current I₁ that flows through the base current supply resistive element 112 all flows into the ground side output control transistor 111. This current I₁ is about 10 μA, for example, under the above mentioned conditions.

In this way, this power supply voltage monitoring device 101 monitors the power supply voltage V_{cc}, and if the power supply voltage V_{cc} is lower than a predetermined value, the output transistor 110 of the signal output circuit 102 turns ON, and if higher than a predetermined value, the output transistor 110 turns OFF.

The current I₁ that flows through the base current supply resistive element 112 is the current required when the output transistor 110 turns ON, but wastes current consumption when the output transistor 110 turns OFF. If the power supply voltage V_{cc} rises, the current consumption further increases. For example, if the boundary of the power supply voltage V_{cc} when the output transistor 110 is turned ON or OFF is 10V under the above conditions, then the wasted current I₁, which flows through the base current supply resistive element 112, is 30 μA if the power supply voltage V_{cc} rises up to 30V.

### SUMMARY OF THE INVENTION

In order to overcome the problems described above, preferred embodiments of the present invention provide a signal output circuit which can decrease the current consumption while securing the base current required for an output transistor of an NPN bipolar transistor, and a power supply voltage monitoring device including such a signal output circuit.

A signal output circuit according to a preferred embodiment of the present invention includes an output transistor of an NPN type bipolar transistor for outputting an output signal, a ground side output control transistor that turns ON and OFF according to an input signal so that turning ON drops the potential of the base of the output transistor to turn OFF the output transistor, and turning OFF raises the potential of the base of the output transistor to turn ON the output transistor, a base current supply resistive element for supplying current from an input power supply to the base of the output transistor, a power supply side output control transistor that is located between the base current supply resistive element and the base of the output transistor, and turns ON and OFF in opposite ways as the ground side output control transistor according to the input signal, a ground side current bypass transistor that turns ON and OFF in the same way as the ground side output control transistor according to the input signal so that turning ON allows the current of the base current supply resistive element to flow, and turning OFF stops the current of the base current supply resistive element from flowing, and a current limitation resistive element located between the ground side current bypass transistor and the base current supply resistive element.

It is preferable that this signal output circuit also includes an inversion circuit to which voltage, between the ground side current bypass transistor and the current limitation resistive element, is input for inverting this voltage to control the power supply side output control transistor.

It is also preferable that this signal output circuit further includes a second current limitation resistive element to be connected to the output of the inversion circuit.

In this signal output circuit, it is preferable that the ground side output control transistor, the power supply side output control transistor and the ground side current bypass transistor are MOS transistors.

In this signal output circuit, it is preferable that the base current supply resistive element, the current limitation resistive element and the second current limitation resistive element are resistors.

The power supply voltage monitoring device according to another preferred embodiment of the present invention is a power supply voltage monitoring device including the above-described signal output circuit, and further including resistive elements connected in series for dividing the power supply voltage, a reference voltage generation circuit for generating the reference voltage, and a comparator for comparing the voltage at a mid-point of the resistive elements connected in series and the reference voltage generated by the reference voltage generation circuit, so as to use the comparison output as an input signal, wherein the output signal of the signal output circuit is output as a power supply voltage monitoring signal.

The signal output circuit according to preferred embodiments of the present invention and the power supply voltage monitoring device including such a signal output circuit allows the current to flow from the base current supply resistive element to the ground side current bypass transistor via the current limitation resistive element when the output transistor of the signal output circuit is OFF, so current consumption can be decreased.

Other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a circuit diagram depicting a signal output circuit according to a preferred embodiment and a power supply voltage monitoring device including such a signal output circuit.

FIG. 2 is a circuit diagram depicting a conventional signal output circuit and a power supply voltage monitoring device comprised thereof.

### DETAILED DESCRIPTION OF PREFERRED EMBODIMENTS

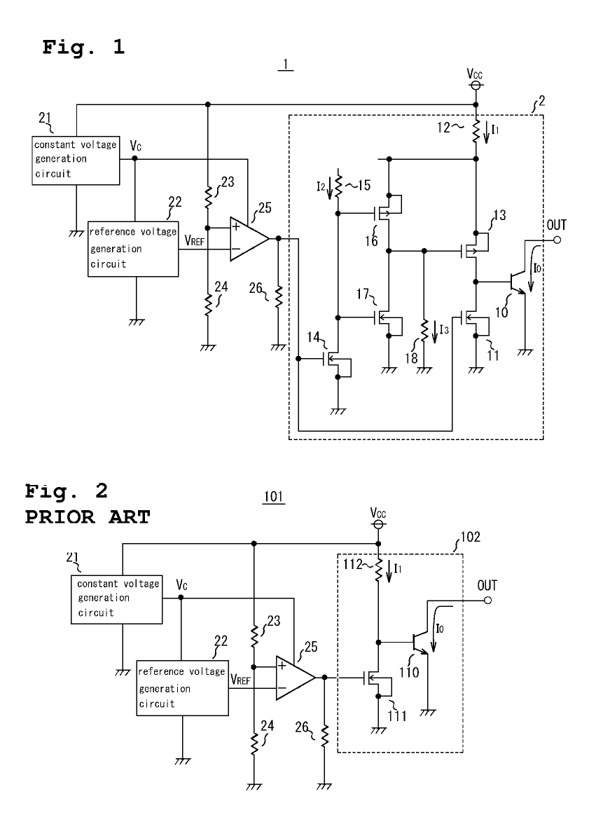

Preferred embodiments of the present invention will now be described with reference to the drawings. FIG. 1 is a circuit diagram depicting the signal output circuit according to a preferred embodiment and a power supply voltage monitoring device including the signal output circuit. This power supply voltage monitoring device 1 has a different signal output circuit from that of the conventional power supply voltage monitoring device 101, and the rest of the constituent elements preferably are essentially the same as the power supply voltage monitoring device 101 shown in FIG. 2. In other words, the power supply voltage monitoring device 1 preferably includes a signal output circuit 2 which outputs the power supply voltage monitoring signal to indicate that the power supply voltage V_{cc} to be monitored is lower than a predetermined value to an output terminal OUT, resistive elements 23 and 24 connected in series for dividing the power supply voltage V_{cc}, a reference voltage generation circuit 22 for generating reference voltage V_{REF}, a comparator 25 where the voltage at a mid-point of the resistive elements 23 and 24 connected in series is input to the non-inversion input terminal, and the reference voltage V_{REF} generated by the reference voltage generation circuit 22 is input to the inversion input terminal, and these voltages are compared and the comparison output is used as the input signal of the signal output circuit 2, a pull-down resistive element 26 which is connected to the output of the comparator 25 at one end and is grounded at the other end, and a constant voltage generation circuit 21 for supplying a predetermined constant voltage V_{c} to the power supply terminals of the reference voltage generation circuit 22 and the comparator 25. Another electronic circuit (not illustrated) for inputting the power supply voltage monitoring signal is connected to the outside of the output terminal OUT.

The signal output circuit 2 preferably includes an output transistor 10 which is an NPN type bipolar transistor for outputting the power supply voltage monitoring signal, which is an output signal of the signal output circuit 2, to the output terminal OUT, a ground side output control transistor 11, which is preferably an N type MOS transistor, that turns ON and OFF according to the input signal so that turning ON drops the potential of the base of the output transistor 10 to turn OFF the output transistor 10, and turning OFF raises the potential of the base of the output transistor 10 to turn ON the output transistor 10, a base current supply resistive element 12 which is a resistor for supplying current from the input power supply (power supply voltage V_{cc}) to the base of the output transistor 10, a power supply side output control transistor 13, which is preferably a P type MOS transistor, that is disposed between the base current supply resistive element 12 and the base of the output transistor 10 and turns ON and OFF in opposite ways as the ground side output control transistor 11 according to the input signal, a ground side current bypass transistor 14 which is preferably an N type MOS transistor, that turns ON and OFF in the same way as the ground side output control transistor 11 according to the input signal so that turning ON allows current of the base current supply resistive element 12 to flow, and turning OFF stops current of the base current supply resistive element 12 from flowing, and a current limitation resistive element 15, which is a resistor disposed between the ground side current bypass transistor 14 and the base current supply resistive element 12. Also, the signal output circuit 2 further includes a P type MOS transistor 16 and an N type MOS transistor 17 connected in series from the connection point between the base current supply resistive element 12 and the current limitation resistive element 15 to the ground potential as an inversion circuit to which voltage, between the ground side current bypass transistor 14 and the current limitation resistive element 15, is input for controlling the power supply side output control transistor 13 by inverting this voltage. The signal output circuit 2 further includes a second current limitation resistive element 18, which is a resistor, to be connected to the output of the inversion circuit, that is the connection point of the P type MOS transistor 16 and the N type MOS transistor 17.

If the divided voltage of the power supply voltage V_{cc} (voltage at the mid-point of the resistive elements 23 and 24 connected in series) is lower than the reference voltage V_{REF}, the comparator 25 outputs low level to the signal output circuit 2 as the comparison output, and thus, the ground side output control transistor 11 turns OFF. At the same time, the ground side current bypass transistor 14 also turns OFF, the voltage between the ground side current bypass transistor 14 and the current limitation resistive element 15 rises, and the N type MOS transistor 17 turns ON. On the other hand, current does not flow through the current limitation resistive element 15, and voltage is not generated at both ends thereof, so the P type MOS transistor 16 turns OFF. Therefore, the voltage at the connection point of the P type MOS transistor 16 and the N type MOS transistor 17 becomes low level, and the power supply side output control transistor 13 turns ON. So the current I₁ that flows through the base current supply resistive element 12 all becomes the base current of the output transistor 10. If the resistance value of the base current supply resistive element 12 is R₁, then the current I₁ is about the current value Vcc/R₁. As a result, the output current I₀, that is the base current multiplied by the current amplification factor (h_{FE}), flows into the output transistor 10. The output current I₀ flows through the output terminal OUT as the power supply voltage monitoring signal, and by the output current I₀, the input voltage of another electronic circuit (not illustrated) drops to the ground side.

If the voltage of the divided power supply voltage V_{cc} is higher than the reference voltage V_{REF}, the comparator 25 outputs high level to the signal output circuit 2 as the comparison output, and thus, the ground side output control transistor 11 turns ON. At the same time, the ground side current bypass transistor 14 also turns ON, and the voltage between the ground side current bypass transistor 14 and the current limitation resistive element 15 becomes ground potential level, and the N type MOS transistor 17 turns OFF. On the other hand, current flows through the current limitation resistive element 15, and the P type MOS transistor 16 turns ON. Therefore, the voltage at the connection point between the P type MOS transistor 16 and the N type MOS transistor 17 become high level, and the power supply side output control transistor 13 turns OFF, and current flows through the second current limitation resistive element 18. In this way, the ground side output control transistor 11 drops the potential of the base of the output transistor 10, turns OFF the output transistor 10, and stops the output current I₀ as the power supply voltage monitoring signal, whereas the current I₁ that flow through the base current supply resistive element 12 is divided into the current I₂ that flows through the current limitation resistive element 15 and the current I₃ that flows through the second current limitation resistive element 18. If the resistance value of the base current supply resistive element 12 is R₁, the resistance value of the current limitation resistive element 15 is R₂ and the resistance value of the second current limitation resistive element 18 is R₃, then the current I₁ becomes roughly a current value of V_{cc}/(R₁+(R₂R₃)/(R₂+R₃)).

The resistance value R₁ of the base current supply resistive element 12 is determined by considering the value of the output current I₀ when the output transistor 10 is ON. The resistive values R₂ and R₃ of the current limitation resistive element 15 and the second current limitation resistive element 18, on the other hand, are determined considering the withstand voltage of the element of the power supply side output control transistor 13 and the P type MOS transistor 16. In other words, the withstand voltage of a normal MOS transistor is about 10V to 15V, so if the power supply voltage V_{cc} is higher than this, the current flows to the base current supply resistive element 12 to drop the voltage so that the voltage to be applied to the transistor elements (power supply side output control transistor 13 and P type MOS transistor 16) becomes the withstand voltage or less. Specifically, if the withstand voltage of the transistor element is 15V and the power supply voltage V_{cc} to be input rises to 30V, the resistance values R₂ and R₃ are both the double of the resistance value R₁, then the voltage that is applied to the element when the output transistor 10 is OFF can be maintained at 15V.

Therefore, if the resistance value of the base current supply resistive element 12 is set to 1 MΩ, and the resistance values R₂ and R₃ of the current limitation resistive element 15 and the second current limitation resistive element 18 are set to 2 MΩ, then the current I₁ that flows through the base current supply resistive element 12 is 15 μA when the power supply voltage V_{cc} is 30V and the output transistor 10 is OFF. In this way, unnecessary current I₁ that flows through the base current supply resistive element 12, when the output transistor 10 is OFF, can be decreased, and the current consumption of the entire signal output circuit 2 and the power supply voltage monitoring device 1 can be decreased.

It is preferable that the second current limitation resistive element 18 is added to prevent the control of the power supply side output control transistor 13 from becoming unstable at startup when the power supply voltage V_{cc} is supplied, but can be omitted. In this case, the resistance value R₂ of the current limitation resistive element 15 must be decreased considering the withstand voltage of the transistor element (e.g., decreased to 1 MΩ).

If the high level voltage of the input signal of the signal output circuit 2 (that is the constant voltage V_{c} to be supplied by the constant voltage generation circuit 21) is a voltage which is sufficient to turn OFF the power supply side output control transistor 13 when the output transistor 10 is OFF, then the input signal of the signal output circuit 2 may be directly input to the power supply side output control transistor 13. In this case, the resistance value R₂ of the current limitation resistive element 15 must be further decreased, and unnecessary current I₁ that flows through the base current supply resistive element 12 when the output transistor 10 is OFF increases somewhat, but the inversion circuit, which includes the P type MOS transistor 16 and the N type MOS transistor 17, and the second current limitation resistive element 18, are unnecessary.

The signal output circuit 2 according to the present preferred embodiment is preferably designed for the power supply voltage monitoring device 1, for example, but may be applied to the case when the power supply voltage V_{cc} of the output stage is relatively high and the NPN type bipolar transistor is used for output, such as the case of the signal output of a motor drive device.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-6. (canceled)

7. A signal output circuit comprising:
an output transistor of an NPN type bipolar transistor arranged to output an output signal;
a ground side output control transistor that turns ON and OFF according to an input signal so that turning ON drops the potential of a base of the output transistor to turn OFF the output transistor, and turning OFF raises the potential of the base of the output transistor to turn ON the output transistor;
a base current supply resistive element arranged to supply current from an input power supply to the base of the output transistor;
a power supply side output control transistor located between the base current supply resistive element and the base of the output transistor and arranged to turn ON and OFF in opposite ways as the ground side output control transistor according to the input signal;
a ground side current bypass transistor, that turns ON and OFF in the same way as the ground side output control transistor according to the input signal so that turning ON allows current of the base current supply resistive element to flow and turning OFF stops the current of the base current supply resistive element from flowing; and
a current limitation resistive element located between the ground side current bypass transistor and the base current supply resistive element.

8. The signal output circuit according to claim 7, further comprising an inversion circuit to which the voltage between the ground side current bypass transistor and the current limitation resistive element is input so as to invert the input voltage to control the power supply side output control transistor.

9. The signal output circuit according to claim 8, further comprising a second current limitation resistive element connected to the output of said inversion circuit.

10. The signal output circuit according to claim 7, wherein the ground side output control transistor, the power supply side output control transistor and the ground side current bypass transistor are MOS transistors.

11. The signal output circuit according to claim 7, wherein the base current supply resistive element, the current limitation resistive element and the second current limitation resistive element are resistors.

12. A power supply voltage monitoring device comprising the signal output circuit according to claim 7, further comprising:
resistive elements connected in series and arranged to divide the power supply voltage;
a reference voltage generation circuit arranged to generate the reference voltage; and
a comparator arranged to compare the voltage at a mid-point of said resistive elements connected in series and the reference voltage generated by said reference voltage generation circuit so as to use the comparison output as an input signal of the signal output circuit, wherein the output signal of the signal output circuit is output as a power supply voltage monitoring signal.

13. A power supply voltage monitoring device comprising the signal output circuit according to claim 8, further comprising:
resistive elements connected in series and arranged to divide the power supply voltage;
a reference voltage generation circuit arranged to generate the reference voltage; and
a comparator arranged to compare the voltage at a mid-point of said resistive elements connected in series and the reference voltage generated by said reference voltage generation circuit so as to use the comparison output as an input signal of the signal output circuit, wherein the output signal of the signal output circuit is output as a power supply voltage monitoring signal.

14. A power supply voltage monitoring device comprising the signal output circuit according to claim 8, further comprising:
resistive elements connected in series and arranged to divide the power supply voltage;
a reference voltage generation circuit arranged to generate the reference voltage; and
a comparator arranged to compare the voltage at a mid-point of said resistive elements connected in series and the reference voltage generated by said reference voltage generation circuit so as to use the comparison output as an input signal of the signal output circuit, wherein the output signal of the signal output circuit is output as a power supply voltage monitoring signal.
